(19) United States
(12) Patent Application Publication
(10) Pub. No.: US 2007/0131987 A1
(43) Pub. Date: Jun. 14, 2007

(54) Vertical image sensor and method for manufacturing the same

(75) Inventor: Jong Min Kim, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/636,216

(22) Filed: Dec. 8, 2006

(30) Foreign Application Priority Data
Dec. 9, 2005 (KR) 10-2005-0120643

(51) Int. Cl. H01L 31/113

(52) U.S. Cl. 257/290

(57) ABSTRACT

Disclosed are a vertical color filter detector group (image sensor) and a method for manufacturing the same, capable of simplifying a manufacturing process by reducing the number of ion implantations and masks for connecting a green sensitive layer and a red sensitive layer to a sensor on a surface of a silicon substrate. The image sensor includes a semiconductor substrate on which first and second conductive type silicon layers are stacked, and having at least two second conductive type regions at different depths from the semiconductor surface, a trench having a bottom lower than a first region farthest away from the semiconductor surface, to set a peripheral border area of a unit pixel, an insulating layer in the trench in contact with an interfacial surface between the semiconductor and the trench, a channel area in an active area between the first and second regions without contacting the interfacial surface between the semiconductor and the trench, and a transfer gate in the insulating layer.

This application claims the benefit of Korean Application No. 10-2005-0120643, filed on Dec. 9, 2005, which is incorporated by reference herein in its entirety.

### BACKGROUND OF THE INVENTION

1. Field of the Invention

The present invention relates to an image sensor. More specifically, the present invention relates to a vertical color filter detector group (image sensor) and a method for manufacturing the same, capable of simplifying a structure and a manufacturing process of the vertical image sensor.

2. Description of the Related Art

Generally, a vertical image sensor includes six or more N-type layers and P-type layers formed on a semiconductor substrate. PN junctions formed by the N-type layers and the P-type layers (e.g., at an interface thereof) have various absorption rates for wavelengths of light, depending on the depth of the junctions. Accordingly, since the absorption rates for wavelengths of light vary according to the position of the PN junction from the surface of the silicon (e.g., the uppermost surface of the N-type and P-type layers), it is possible to filter colors in a vertical direction (e.g., form a vertical color filter detector group, or vertical image sensor).

FIG. 1 is a graph showing light absorption coefficients and light transmission depths according to wavelengths of light in silicon. In a conventional CMOS image sensor in which all P-N junctions corresponding to separate colors are formed at a particular depth, red light can be absorbed at a depth of about 10 μm or more under the surface of silicon, and green light can be absorbed at a depth of about 1.0 μm under the surface of silicon. However, blue light is absorbed at a depth of only about 0.3 μm (that is, 3000 Å) under the surface of silicon, thereby reducing an efficiency of the color reproduction of blue light.

The color reproduction of a product is actually estimated based on a B/G ratio, and the standard range of the B/G ratio is 0.6 to 1.0. Here, the upper limit value of 1.0 is an ideal value, but the lower limit value of 0.6 is generally available, in practice. In order to prevent the degradation of the sensitivity of such a blue signal, a blue filter process must be carried out prior to a green filter process.

Generally, electrons generated due to incidence of light onto a PN junction are detected in the N-type layer. The P-type layer is grounded so as to receive holes created due to the light incidence. Meanwhile, each vertical image sensor includes a blue-sensitive layer, a green-sensitive layer, and a red-sensitive layer. First, the blue-sensitive layer comprises an N-type layer closely adjacent to the surface of silicon, the red-sensitive layer comprises an N-type layer having the greatest depth from the surface of silicon, and the green-sensitive layer comprises an N-type layer formed between the blue-sensitive layer and the red-sensitive layer. Three active pixel sensor circuits are provided for the three vertical color detection units aligned at the same position at different depths. In addition, a contact plug must be formed from the green-sensitive layer, the red-sensitive layer, and the blue-sensitive layer to the circuitry contact in the silicon surface.

Conventional technologies relative to the vertical image sensor are disclosed in U.S. Pat. No. 6,930,336 B1, entitled “Vertical-Color-Filter Detector Group with Trench Isolation,” U.S. Pat. Appl. Publ. No. 2002/0058353 A1, entitled “Vertical-Color-Filter Detector Group and Array,” and U.S. Pat. No. 6,632,702 B2, entitled “Vertical-Color-Filter Detector Group and Array.” According to the conventional technologies, in order to sense electron charges detected from the red-sensitive layer, the green-sensitive layer, and the blue-sensitive layer, three active pixel sensor (APS) circuits are required for each pixel as shown in FIG. 2.

FIG. 2 is a circuit diagram showing a three-transistor APS mode (3Tr APS mode) or circuit for reading red, green, and blue signals. If the three-transistor APS mode is employed for an active pixel sensor circuit, nine transistors are required in order to sense red, green and blue (RGB) signals for one pixel. If a four-transistor APS mode or circuit is employed for the active pixel sensor circuit, 12 transistors are required in order to sense RGB signals for one pixel. However, these APS circuits cause the expansion of a transistor area in each pixel area, thereby reducing a light detection area (or a proportion thereof) in the entire pixel area.

FIG. 3 is a sectional view showing a structure of a conventional vertical image sensor, isolated using a conventional ion implantation process. As shown in FIG. 3, according to the conventional technology, in order to connect the red-sensitive layer and the green-sensitive layer to sensor circuits formed on the silicon surface, respectively, ion implantation and a mask are necessary for isolation and connection (using a contact plug, represented by the diagonally-hatched, rounded implant regions in the interior of epitaxial layers 66 and 72) in each layer formed after the red-sensitive layer and the green-sensitive layer have been formed. However, this makes a manufacturing process complex, thereby increasing manufacturing costs.

The detailed process is disclosed in U.S. Pat. No. 6,632,702 B2, entitled “Vertical-Color-Filter Detector Group and Array.”

FIG. 4 is a sectional view showing the structure of a conventional trench-isolated vertical image sensor. As shown in FIG. 4, when trenches are formed for the purpose of connection (using contact plugs) relative to the red-sensitive layer and the green-sensitivity layer, not only a new mask, but also additional coating and etching processes for photoresist are required in order to form the trenches

### SUMMARY OF THE INVENTION

The present invention has been made to solve the above problem occurring in the prior art, and therefore, it is an object of the present invention to provide a vertical image sensor and a method for manufacturing the same, capable of sensing charges detected from each layer by using one sensing circuit in a structure in which first conductive type blue, green, and red sensitive layers are aligned separately from each other in a vertical direction to the surface of a silicon substrate by means of second conductive type layers such that blue, green and red colors can be detected at the same location or unit pixel.

It is another object of the present invention to provide a vertical image sensor and a method for manufacturing the same, capable of simplifying an active pixel sensor circuit that senses signal charges from RGB layers by reducing the number of the active pixel sensor circuits from three to one and increasing an aperture ratio (the efficiency of a detection area) by reducing an area of the unit pixel for the active pixel sensor circuit.

In addition, it is still another object of the present invention to provide a vertical image sensor and a method for manufacturing the same, capable of simplifying a manufacturing process by reducing the number of ion implantations and masks used to form a path for connecting a green sensitive layer and a red sensitive layer to an active pixel sensor circuit on a surface of a silicon substrate.

According to one aspect of the present invention, there is provided a vertical image sensor including a first conductive type substrate, a first conductive type silicon layer thereon, and at least two second conductive type silicon layers thereon at different depths from a surface of the substrate, a trench having a bottom below a first silicon layer of the second conductive type silicon layers farthest away from the surface of the semiconductor, so as to set a peripheral border area of a unit pixel, an insulating layer in the trench in contact with an interfacial surface between the semiconductor and the trench, a channel area in an active area between the first and second second conductive type silicon layers without contacting the interfacial surface between the semiconductor and the trench, and a transfer gate in the insulating layer.

According to another aspect of the present invention, there is provided a method for manufacturing a vertical image sensor, the method including the steps of forming a first epitaxial layer having a first conductive type on a first conductive type substrate, forming a first silicon layer having a second conductive type on a surface of the first epitaxial layer, forming a second epitaxial layer having the first conductive type on the first silicon layer, forming a second silicon layer having the first conductive type and a third silicon layer having the second conductive type, separated from each other in a longitudinal direction, by implanting a second conductive type dopant onto a surface of the second epitaxial layer, forming a trench having a predetermined depth in the first conductive type substrate such that the first and third silicon layers are separated from other active areas, implanting a first conductive type dopant onto a sidewall of the trench such that the second silicon layer is electrically connected to the first conductive type substrate, depositing an insulating material in the trench below an upper surface of the first silicon layer, forming a gate insulating layer on the sidewall of the trench, and forming a transfer gate in the trench below the third silicon layer.

### BRIEF DESCRIPTION OF DRAWINGS

FIG. 1 is a graph showing light absorption coefficients and light transmission depths according to wavelengths of light in silicon;

FIG. 2 is a circuit diagram showing a three-transistor APS mode for reading red, green, and blue signals;

FIG. 3 is a sectional view showing a structure of a conventional vertical image sensor isolated through a conventional ion implantation process;

FIG. 4 is a sectional view showing the structure of a conventional trench-isolated vertical image sensor;

FIG. 5 is a sectional view showing the structure of a vertical color detector group having a trench-type charge transfer gate according to the present invention;

FIGS. 6A to 6J are sectional views showing a method for manufacturing a vertical image sensor according to the present invention;

FIGS. 7 and 8 are schematic and/or layout views showing an isolation layer, an active pixel area, and a transistor area viewed from a top of a semiconductor substrate;

FIG. 9A is a circuit diagram showing a three-transistor APS mode for reading red, green and blue signals;

FIG. 9B is a circuit diagram showing a four-transistor APS mode for reading red, green, and blue signals;

FIG. 10A is a timing diagram showing the operation of active pixel sensor circuits shown in FIG. 9A;

FIG. 10B is a timing diagram showing the operation of active pixel sensor circuits shown in FIG. 9B;

FIG. 11A is a plan view showing a vertical image sensor according to the present invention;

FIG. 11B is a sectional view showing a vertical image sensor, which is taken along a dashed line shown in FIG. 11A;

FIGS. 12A to 12F are sectional views showing a method for manufacturing a vertical image sensor according to the present invention; and

FIGS. 13A and 13B are sectional views showing a method for manufacturing a vertical image sensor by using two mask layers.

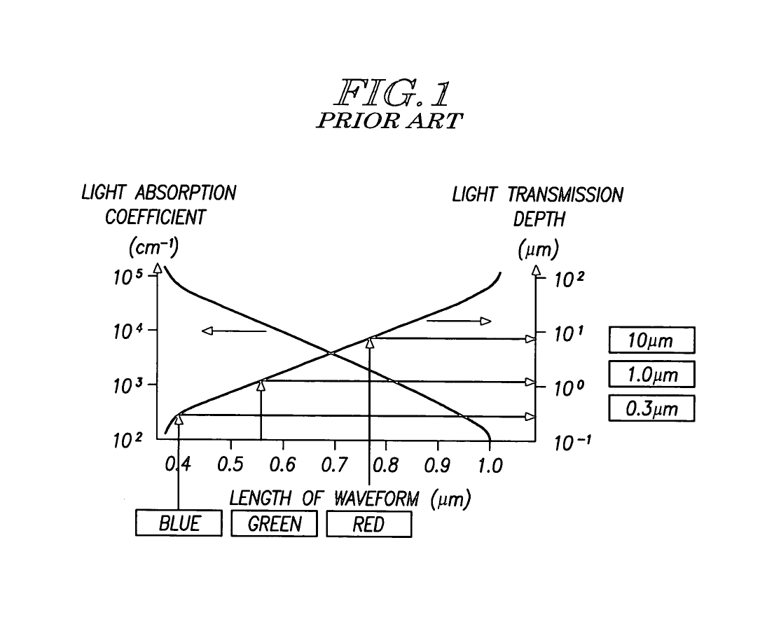

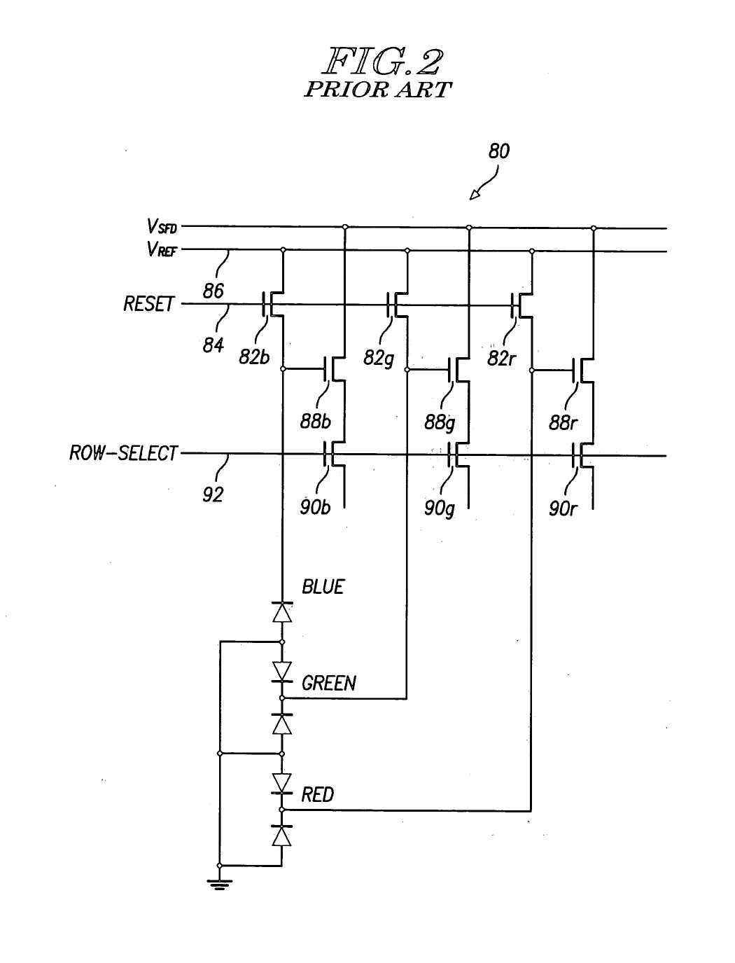

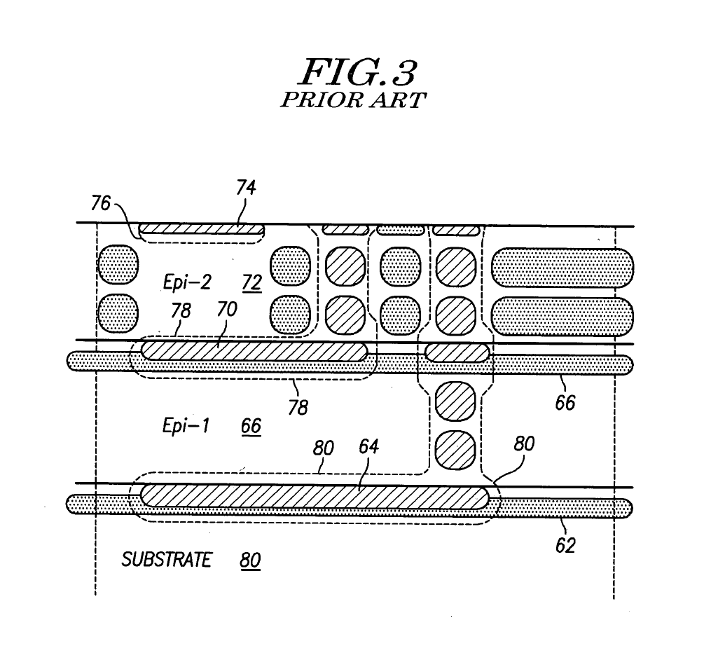

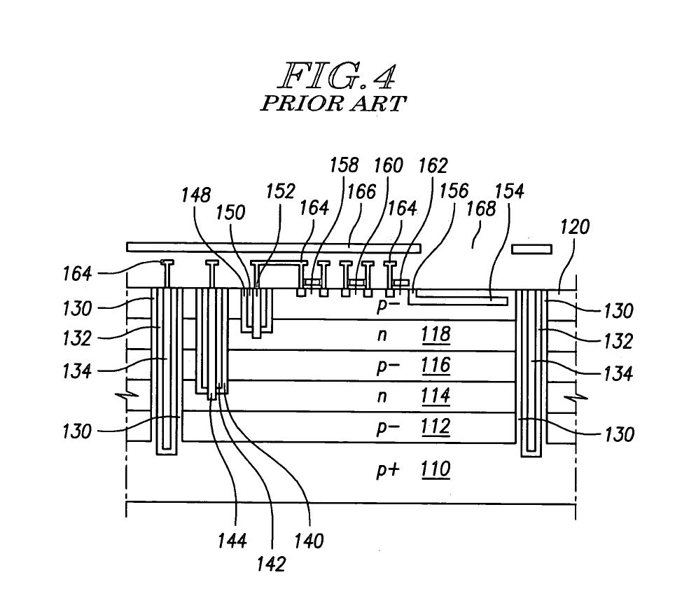

### DETAILED DESCRIPTION OF THE INVENTION

Hereinafter, a vertical image sensor and a method for manufacturing the same according to the present invention will be described with respect to accompanying drawings.

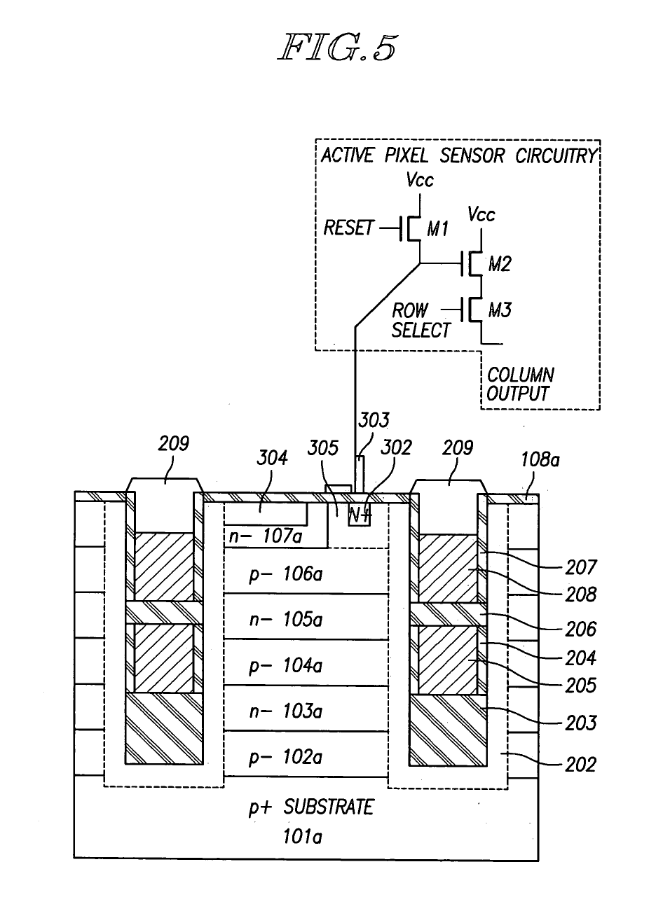

FIG. 5 is a sectional view showing the structure of a vertical color detector group (image sensor) having a trench-type charge transfer gate according to the present invention. As shown in FIG. 5, the vertical image sensor for detecting charges by a transistor having a trench-type gate includes a second conductive type blue-sensitive layer 107a which is formed on the upper surface of a first conductive type (P-type) semiconductor substrate 101 including a single crystal p⁺ substrate 101a, a second conductive green-sensitive layer 105a below the second conductive type blue-sensitive layer 107a, and a second conductive type red-sensitive layer 103a below the second conductive type green-sensitive layer 105a. In addition, the vertical image sensor includes a first silicon epitaxial layer 102a, a second silicon epitaxial layer 104a, and a third silicon epitaxial layer 106a, which have a first conductive type, among the second conductive blue-sensitive layer 107a, the second green-sensitive layer 105a, and the red-sensitive layer 103, connected to a semiconductor substrate 101a.

In addition, a cell of each pixel includes a first trench type charge transfer gate 205 and a second trench type charge transfer gate 208, and the first and second transfer gates 205 and 208 are isolated from each other by isolation layers that may have a shallow trench isolation (STI) structure, including first, second, and third insulating layers 203, 206, and 209. In other words, two trench type charge transfer gates may exist in an isolation area or trench.

Each trench type charge transfer gate is prepared in the form of a layer in the entire cell area. Meanwhile, the first trench type charge transfer gate 205 extends from the upper part of the red-sensitive layer 103a to the lower part of the green-sensitive layer 105a in a vertical direction of the trench. In other words, a first trench type transistor has the red-sensitive layer 103a as a source, the green-sensitive layer 105a as a drain, and the first trench type charge transfer gate 205 as a gate.

In addition, the second trench type charge transfer gate 208 includes the upper part of the green-sensitive layer 105a and the lower part of the blue-sensitive layer 107a in a vertical direction of the trench. In other words, a second trench type transistor has the green-sensitive layer 105a as a source, the blue-sensitive layer 107a as a drain, and the second trench type charge transfer gate 208 as a gate.

In addition, the blue-sensitive layer 107a is electrically connected to one active pixel sensor circuit element. Here, the active pixel sensor circuitry can be formed in a P-well region 305 isolated with the blue-sensitive layer 107a, even though it is not shown in FIG. 5. In addition, a first conductive type impurity layer 304 is formed on the surface of the blue-sensitive layer 107a to provide the blue-sensitive layer 107a with characteristics of a pinned diode. The first conductive impurity layer 304 can be formed after formation of a plurality of transistor gates and spacers thereof constituting the active pixel sensor circuitry.

In addition, the active pixel sensor circuitry can comprise an N-channel source follower transistor M2 comprising or consisting of: a gate connected to the blue-sensitive layer 107a through a N+ diffusion region 302 in the P well region 305, a drain connected to a voltage supply line Vcc, and a source connected to an a column output. In addition, the N-channel source follower transistor M2 can be formed on the third silicon epitaxial layer 106a.

In addition, the active pixel sensor circuitry can include a reset transistor M1 connected between the blue-sensitive layer 107a and the reference voltage (e.g., voltage supply Vcc), and an output or output enable transistor M3 between a source of the source follower transistor M2 and a column output, and having a gate connected to a row select line. In addition, the active pixel sensor circuitry can further include a charge transfer transistor having a source connected to the blue-sensitive layer 107a, a gate connected to a charge transfer line, and a floating drain 303 connected to the gate of the source-follower transistor M2.

In addition, the N-channel source-follower transistor can be formed in the third silicon epitaxial layer 106a, of which a gate is connected to a floating drain contact of the charge transfer transistor, and a drain and source are connected to a voltage supply line.

Furthermore, the vertical image sensor may include a reset transistor connected between a reference voltage and the floating drain contact of the charge transfer transistor, and an output (enable) transistor having a gate connected to the row select line and being connected between the source of the N-channel source-follower transistor and the column output line.

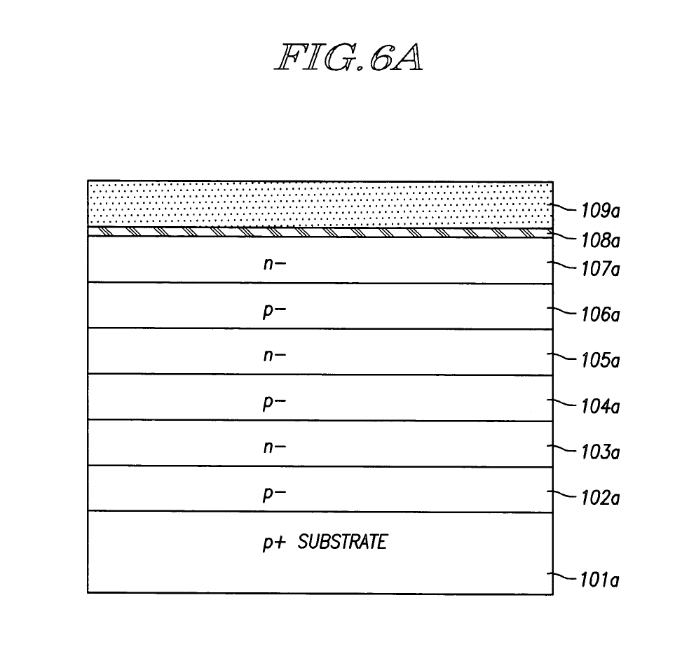

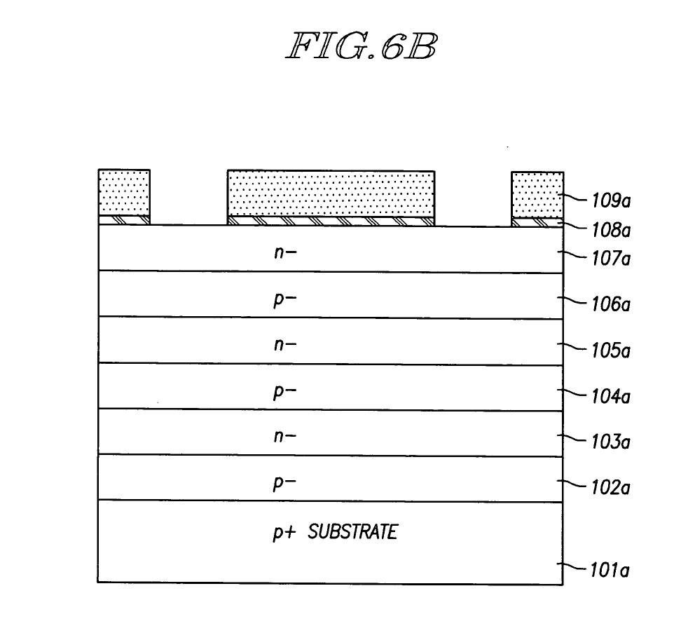

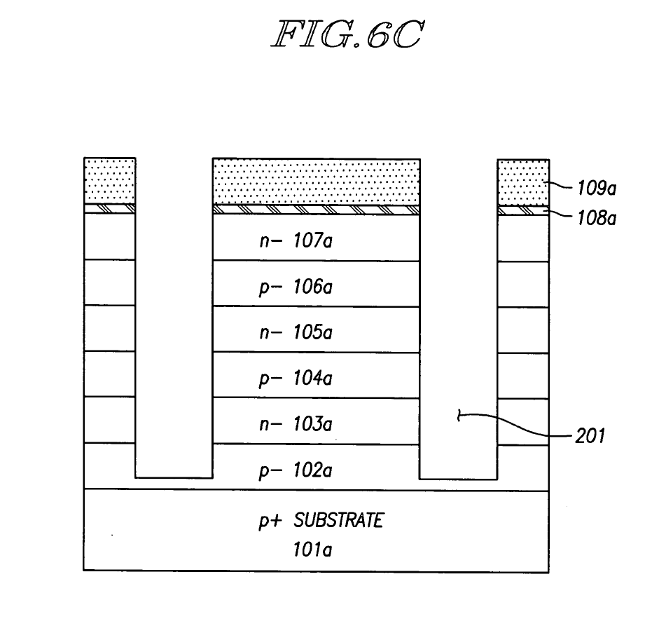

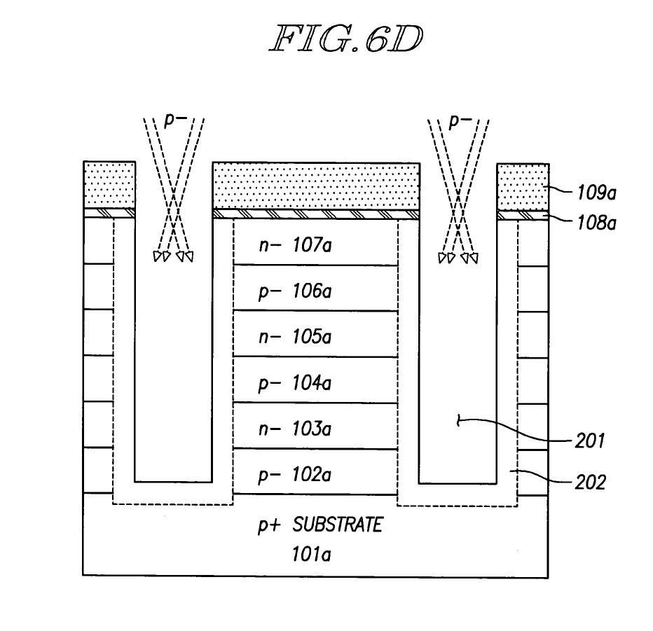

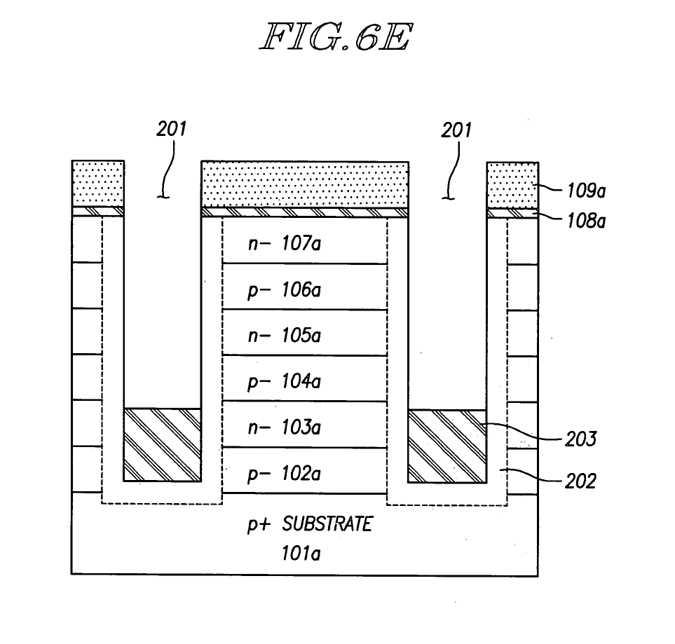

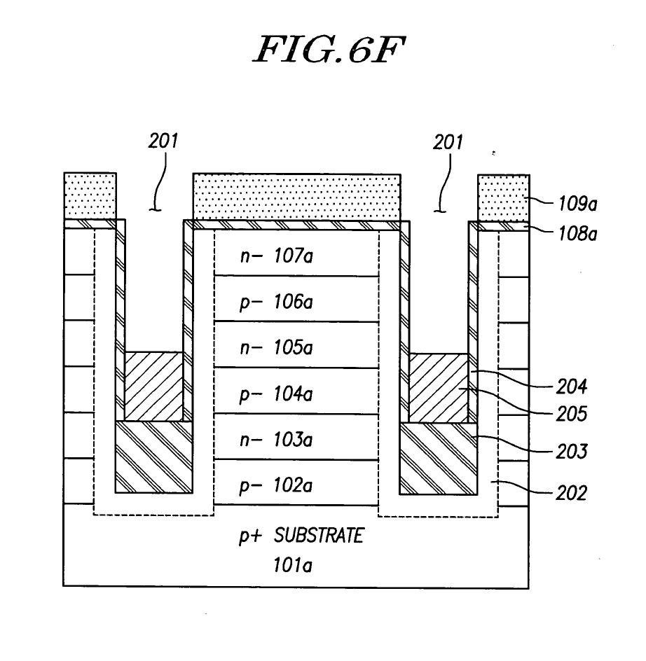

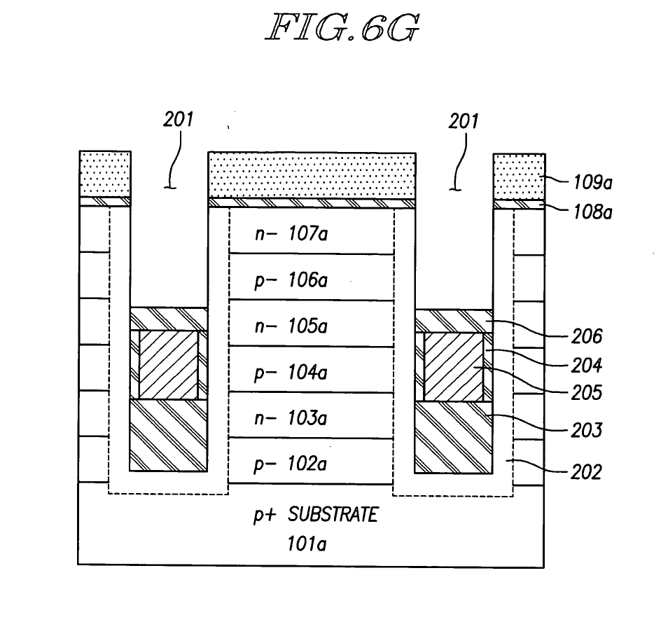

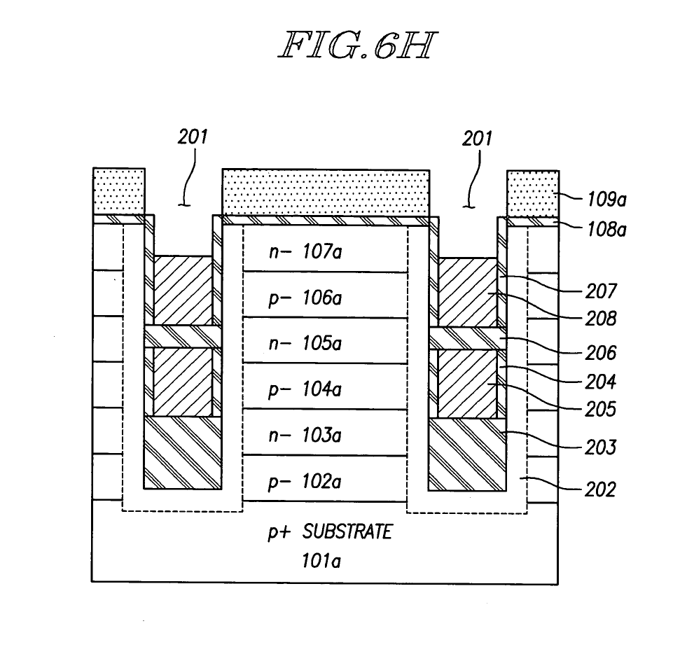

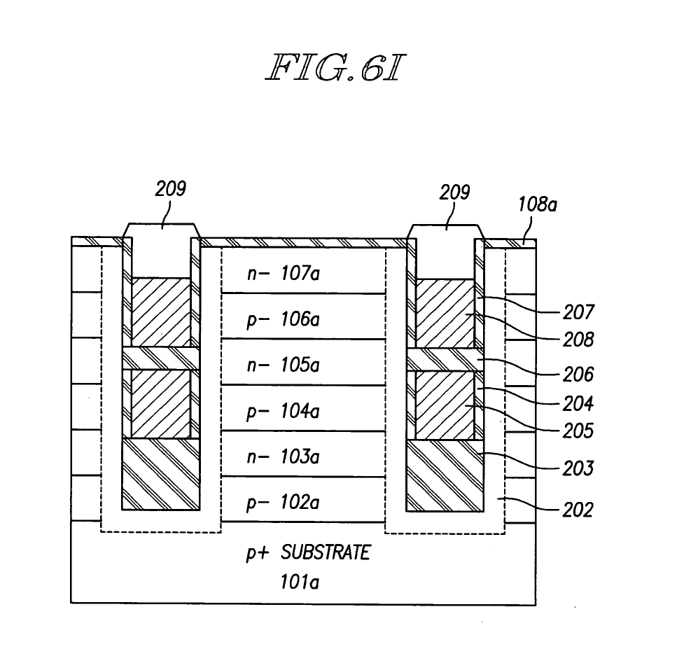

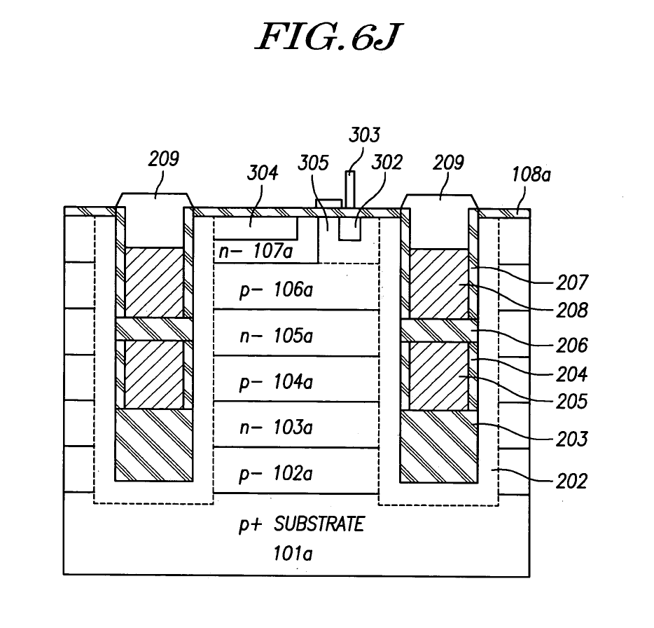

FIGS. 6A to 6J are sectional views showing a method for manufacturing a vertical image sensor according to the present invention.

As shown in FIG. 6A, a first conductive type (e.g., P−) epitaxial layer 102a is formed on the first conductive type (e.g., P+) semiconductor substrate 101a. Alternatively, the first conductive type may be N-type, and the second conductive type may be P-type. Thereafter, the second conductive type red-sensitive layer 103a, the first conductive type impurity layer 104a, the second conductive type green-sensitive layer 105a, the first conductive type impurity layer 106a, and the second conductive type blue-sensitive layer 107a are sequentially formed on the surface of the semiconductor substrate 101a. The second conductive type layer 103a may be formed by ion implantation into the first epitaxial layer 102a, epitaxial growth of a separate n⁻-doped layer, or chemical vapor deposition of silicon (e.g., from a silane) in the presence of an N-type dopant source. In the first case, the thickness of the epitaxial layer corresponds to the total thicknesses of the second conductive type red-sensitive layer 103a through the second conductive type blue-sensitive layer 107a. In the latter two cases, each layer is formed sequentially on the underlying layer.

Meanwhile, a method for forming the layers according to an embodiment of the present invention is described below.

First, the second conductive type (N-type) dopants and the first conductive type (P-type) dopants are implanted onto the entire surface of the semiconductor substrate 101a without an additional mask but with different ion implantation energies, thereby sequentially forming the second conductive type red-sensitive layer 103a, the first conductive type layer 104a, the second conductive type green-sensitive layer 105a, the first conductive type layer 106a, and the second conductive type blue-sensitive layer 107a on the surface of the semiconductor substrate 101a. In such a case, each successive implantation may be performed at a slightly higher dose than the preceding implantation, to ensure that the conductivity type of the layer is the desired/predetermined conductivity type. Alternatively, the first conductive type (P−) silicon epitaxial layer 102a can be formed on the first conductive type (P+) semiconductor substrate 101a (e.g., by epitaxial growth of silicon). Then, second conductive type (N-type) ions are implanted onto the first conductive type silicon epitaxial layer 102a without an additional mask, thereby forming the red-sensitive layer 103a, then the first conductive silicon epitaxial layer 104a is formed on the red-sensitive layer 103a (e.g., by epitaxial growth of silicon). Thereafter, second conductive type ions are implanted on the entire surface of the resultant structure without a mask, thereby forming the green-sensitive layer 105a. Then, the first conductive type silicon epitaxial layer 106a is formed on the green-sensitive layer 105a (e.g., by epitaxial growth of silicon). Thereafter, the second conductive ions are implanted onto the entire surface of the resultant surface without a mask, thereby forming the blue-sensitive layer 107a. In general, each of the ion implantations for forming red-sensitive layer 103a, green-sensitive layer 105a, and blue-sensitive layer 107a may comprise the same dopant species, in the same dose, and at the same implant energy, although the conditions may also vary, in accordance with design choices and optimization of certain color detection parameters.

In a further alternative embodiment, the first conductive type silicon epitaxial layer 102a may be formed by epitaxial growth on the first conductive type (P+) semiconductor substrate 101a, and a second conductive type silicon epitaxial layer 104a can be formed on the first conductive silicon epitaxial layer 102a by epitaxial growth, thereby forming the red-sensitive layer 103a. Thereafter, the first conductive type silicon epitaxial layer 104a is formed on the red-sensitive layer 103a by epitaxial growth, and a second conductive type silicon epitaxial layer is formed on the first conductive type silicon epitaxial layer 104a by epitaxial growth, thereby forming the green-sensitive layer 105a. Then, the first conductive type silicon epitaxial layer 106a is formed on the green-sensitive layer 105a by epitaxial growth, and a second conductive type silicon epitaxial layer is formed on the first conductive silicon epitaxial layer 106a by epitaxial growth, thereby forming the blue-sensitive layer 107a. Again, the species and/or dopant levels incorporated into each of the first conductive type epitaxial silicon layers may be the same or different, in accordance with design choices and image sensor parameter optimization.

Next, a buffer oxide layer 108a and a nitride layer 109a are sequentially formed on the entire surface of the semiconductor substrate 101a having the blue, green, and red-sensitive layers 107a, 105a, and 103a thereon. Each layer in the pixel active area may be formed by one (or more) of the various schemes as described above.

At this time, from an uppermost (horizontal) surface of the silicon substrate, the first silicon epitaxial layer 102a may be formed at (or may have) a depth (or distance) of about 6 μm, the red-sensitive layer 103a may be formed at (or may have) a depth of about 4.0 pm, the second silicon epitaxial layer 104a may be formed at (or may have) a depth of about 2.5 μm, the green silicon layer 105a may be formed at (or may have) a depth of about 1.7 μm, the third silicon epitaxial layer 106a may be formed at (or may have) a depth of about 0.9 μm, and the blue-sensitive layer 107a may be formed at (or may have) a depth of 0.35 μm. Selection of implantation energies suitable for providing such layer depths is well within the abilities of those skilled in the art.

As shown in FIG. 6B, the nitride layer 109a and the buffer oxide layer 108a are selectively patterned through a photolithography process, thereby defining an isolation area. As shown in FIG. 6C, the resultant structure is selectively etched to a predetermined depth (generally into the first silicon epitaxial layer 102a) using the nitride layer 109a and the buffer oxide layer 108a as a mask, thereby forming a trench 201.

As shown in FIG. 6D, first conductive type (P-type) ions are tilt implanted onto sidewalls of the trench 201 at a predetermined angle in order to connect the second silicon epitaxial layer 104a and the third silicon epitaxial layer 106a having the first conductive type to the semiconductor substrate 101ausing the nitride layer 109a and the buffer oxide layer 108a as a mask, thereby forming a first conductive impurity layer 202. At this time, the tilt angle is in the range of 5° to 15°. If rotation is performed through two steps between angles of 0° and 180° and angles of 90° and 270°, the first conductive type impurity layer 202 is formed at sidewalls of only two lateral sides opposite to each other among four lateral sides of the active pixel area, thereby connecting the semiconductor substrate 101a to the second and third silicon epitaxial layers 104a and 106a having the first conductive type. Meanwhile, if the rotation is performed through four steps between angles of 0° and 360°, the first conductive impurity layer 202 is formed at sidewalls of four lateral sides of the active pixel area, thereby connecting the semiconductor substrate 101a to the second and third silicon epitaxial layers 104 and 106a having the first conductive type.

In addition, although the first conductive type impurity layer 202 is formed through the tilt ion implantation, the first conductive type impurity layer 202 can also be formed on the sidewall of the trench 201 by performing a thermal process in a dopant gas atmosphere. Selection of suitable dopant gases (such as diborane, phosphine, arsine, and halogenated or alkylated analogs thereof) and conditions for thermal dopant implantation are also within the ability of those skilled in the art.

As shown in FIG. 6E, after forming a first insulating layer 203 on the entire surface of the semiconductor substrate 101a including the trench 201, the first insulating layer 203 is etched back such that the insulating layer 203 remains lower than the red-sensitive layer 103a (e.g., insulating layer 203 has an uppermost surface below the uppermost surface of red-sensitive layer 103a).

As shown in FIG. 6F, a first gate insulating layer 204 is formed on the surface of the trench 201. At this time, the first gate insulating layer 204 can be formed by depositing a thin film (e.g., conformally, by chemical vapor deposition of silicon dioxide and optional densification) or by performing an oxidation process on the exposed sidewalls of the trench 201. Then, polysilicon is deposited on the entire surface of the semiconductor substrate 101a including the first gate insulating layer 204 and the first insulating layer 203, and the deposited polysilicon is selectively etched back such that (a predetermined thickness of) the polysilicon remains in the trench 201, thereby forming a first transfer gate 205.

As shown in FIG. 6G, after forming a second insulating layer 206 on the entire surface of the semiconductor substrate 101a including the first transfer gate 205, the second insulating layer 206 is selectively etched back, thereby forming a second isolation layer in the trench 201. Thus, when the second isolation layer comprises a material that is not selectively etchable relative to the first gate insulating layer 204, the first gate insulating layer 204 is also removed, as shown in FIG. 6G. At this time, the second isolation layer is formed lower than the green-sensitive layer 105a (e.g., the second insulating layer 206 has an uppermost surface below the uppermost surface of green-sensitive layer 105a).

As shown in FIG. 6H, a second gate insulating layer 207 is formed on the semiconductor substrate 101a, and polysilicon is deposited on the second gate insulating layer 207 and then selectively etched back, thereby forming a second transfer gate 208 in the trench 201. Alternatively, when the second isolation layer 206 comprises a material (e.g., silicon dioxide) that is selectively etchable relative to the first gate insulating layer 204 (e.g., hafnium dioxide), the first gate insulating layer 204 will generally remain along the sidewall of the trench 201, and can also serve as the second gate insulating layer.

As shown in FIG. 6I, after forming a third insulating layer 209 on the entire surface of the semiconductor substrate 101a, a chemical mechanical polishing process is performed with respect to the entire surface of the semiconductor substrate 101a by setting a middle of the pad oxide layer 109a as an end point so as to selectively remove the third insulating layer 209 and the nitride layer 109a, thereby forming a third isolation layer in the trench 201. Then, as shown in FIG. 6J, a typical CMOS process can be performed in order to form a plurality of transistors constituting the active pixel sensor circuitry, for sensing signals from the first and second transfer gates 205 and 208 and the red, green, and blue-sensitive layers 103a, 105a, and 107a. More specifically, a P well 305 is formed by a selective ion implantation process. After etching the oxide layer 108a selectively, a gate oxide layer is formed on blue-sensitive layer 107a and P well 305. Afterward, a plurality of gate patterns (or transistor gates) are formed by depositing and patterning a polysilicon layer. At this time, a lightly doped drain (LDD) structure can be formed by an N-type impurity implantation, and further sidewalls for spacers can be formed at sides of the gate patterns. After then, a P+ diffusion region 304 is selectively formed on a top portion of the blue-sensitive layer 107a. In addition, an N+ diffusion region 302 may be formed by N-type impurity implantation into the P well region 305.

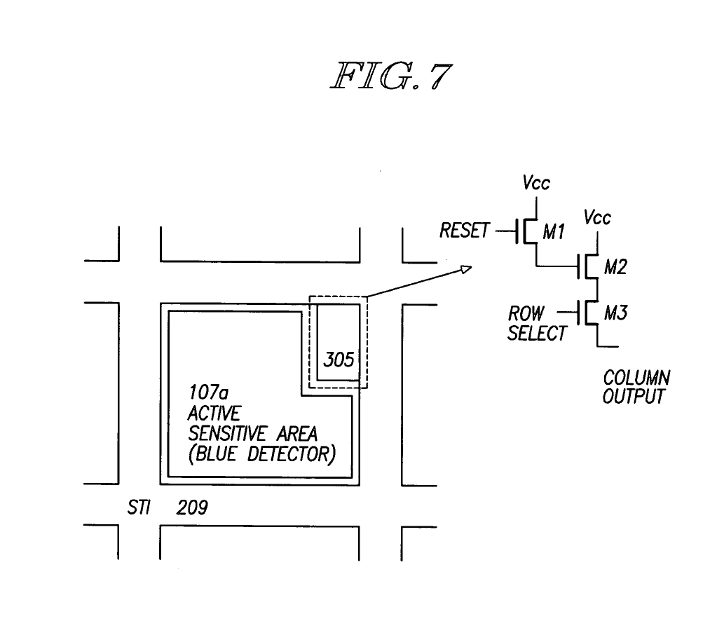

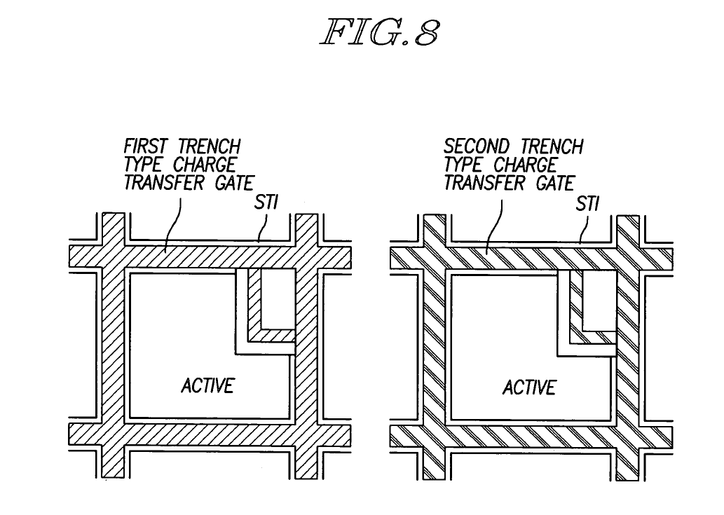

FIGS. 7 and 8 are schematic and/or layout views showing the isolation layer, the active pixel area, and the transistor area from a top of the semiconductor substrate. As shown in FIGS. 7 and 8, the transistor area 305 may be isolated and/or divided by the third insulating layer 209 in the trench or through a well ion implantation process. However, in order to make the blue-sensitive layer 107a into a pinned diode, high-density first conductive type ions are implanted, thereby forming the first conductive impurity layer 304 on the surface of the blue sensitive layer 107a.

Only one active pixel sensor circuit is connected to the blue-sensitive layer 107a in one pixel cell. However, the active pixel sensor circuit is not (directly) connected to the red-sensitive layer 103a and the green-sensitive layer 105a.

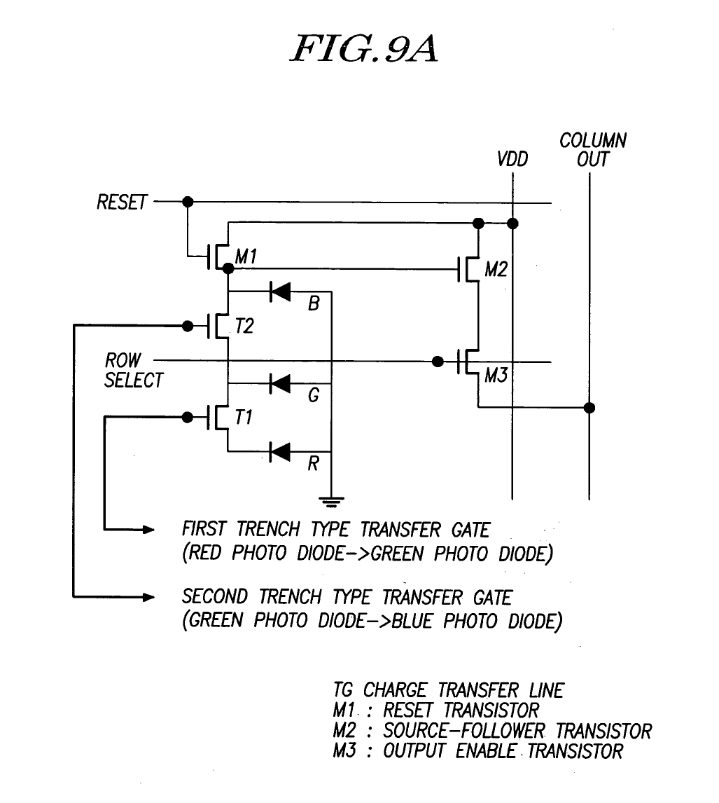

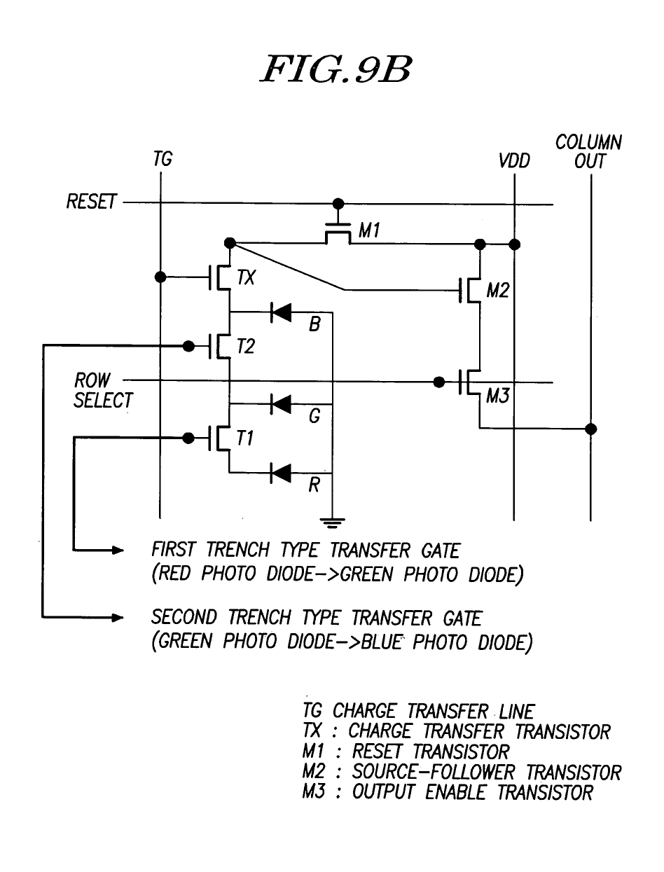

FIG. 9A is a circuit diagram showing a three-transistor APS mode circuit for reading red, green, and blue signals, and FIG. 9B is a circuit diagram showing a four-transistor APS mode circuit for reading red, green, and blue signals. Hereinafter, the difference between a circuit of sensing charges of RGB signals according to the present invention and a conventional circuit will be described. However, the present invention may be applicable to a system or sensor for detecting yellow, cyan and magenta (YCM) signals/colors.

Typical three-transistor APS mode or four-transistor APS mode active pixel sensor circuits have the same structure as the conventional active pixel sensor circuits. However, active pixel sensor circuits are not connected to the red, green, and blue-sensitive layers, respectively, but one active pixel sensor circuit is exclusively connected to the blue-sensitive layer 107a.

Accordingly, in order to read signal charges from the green and red-sensitive layers through the active pixel sensor circuit, first and second trench type transfer gates T1 and T2 are formed (or interposed) among the red, green, and blue-sensitive layers. In this case, the first trench type transfer gate T1 transfers signal charges to the green-sensitive layer from the red-sensitive layer, and the second trench-type transfer gate T2 transfers signal charges to the blue-sensitive layer from the green-sensitive layer, so that signal charges can be read by one active pixel sensor circuit.

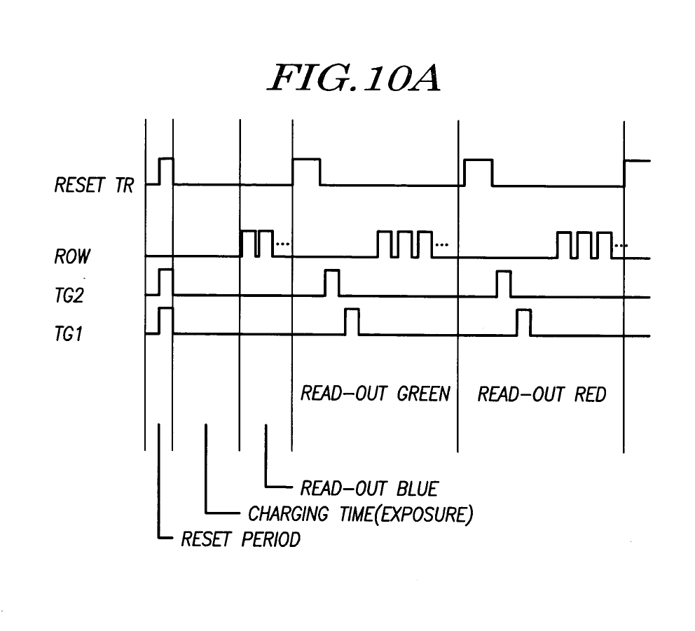

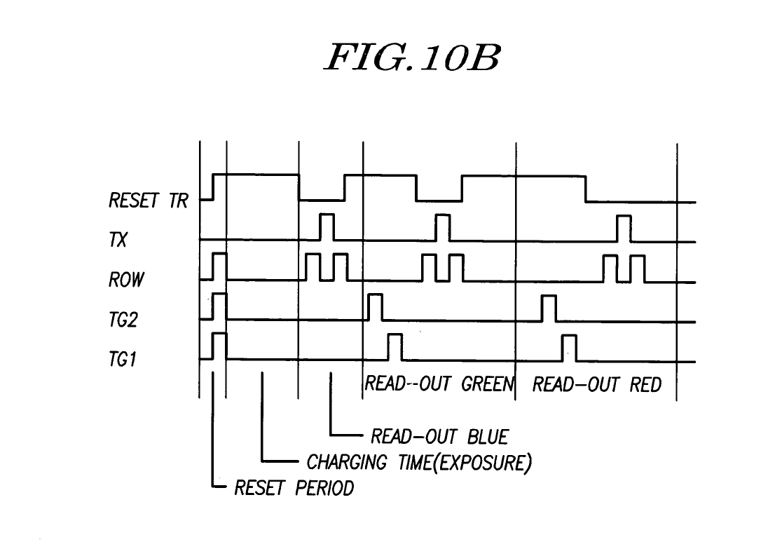

FIG. 10A is a timing diagram showing the operation of the active pixel sensor circuit shown in FIG. 9A, and FIG. 10B is a timing diagram showing the operation of the active pixel sensor circuit shown in FIG. 9B. The timing diagrams shown in FIGS. 10A and 10B differ from those of the conventional technology.

Hereinafter, the sequence of reading RGB signal charges will be described. The sequence of reading the RGB signal charges in the three-transistor APS mode active pixel sensor circuit is similar to that of the four-transistor APS mode active pixel sensor circuit. Hereinafter, description will be made in relation to the four transistor APS mode.

A first step is a reset step in which the trench-type transfer gates T1 and T2, a transfer transistor Tx, and a reset transistor (Reset Tr) are turned on, thereby resetting all the red, green, and blue-sensitive layers. In a second step, the reset transistor (Reset Tr), the gates T1 and T2, and the transfer transistor Tx are turned off, thereby charging the color-sensing photodiodes with electric charges. In this case, the red, green, and blue-sensitive layers are charged with electric charges by opening a lens. In a third step, charges from the blue-sensitive layer are sensed through the active pixel sensor circuit. This step is basically performed through the same driving scheme as that of the typical four-transistor APS mode active pixel sensor circuit.

The reset transistor (Reset Tr) M1 is then turned on, then off so that a floating drain node of the transfer transistor (Tx Tr) is reset, and then a reset level is sensed. Thereafter, the transfer transistor (Tr Tx) is turned on and then off so that electric charges from the blue-sensitive layer are transferred to the floating drain node, and then a signal level of the floating drain node is sensed. Accordingly, the reset level and the signal level are obtained.

Conventionally, in the third step, all row lines are sequentially driven, so RGB signals are read with respect to column lines. In contrast, according to the present invention, in the third step, all row lines are sequentially driven, so only signals of the blue-sensitive layer are read.

The fourth step is to read signals of the green-sensitive layer. The second trench type transfer gate T2 is turned on and then off in order to transfer charges of the green-sensitive layer to the blue-sensitive layer. Charges are transferred to the blue-sensitive layer from the green-sensitive layer in all pixels through one transistor driving process. Thereafter, in order to transfer charges from the red-sensitive layer to the green-sensitive layer in all pixels, the first transfer gate T1 is turned on and then off. Green charge signals transmitted to the blue-sensitive layer are read through the same procedure as that of the third step for reading the blue-sensitive layer.

In a fifth step, signals of the red-sensitive layer are read. The second transfer gate T2 is turned on and then off in order to transfer charges of red signals, which have been previously transmitted to the green-sensitive layer in the fourth step, to the blue-sensitive layer. The following procedure is identical to that of the third step. In other words, blue, green, and red signals are sequentially read.

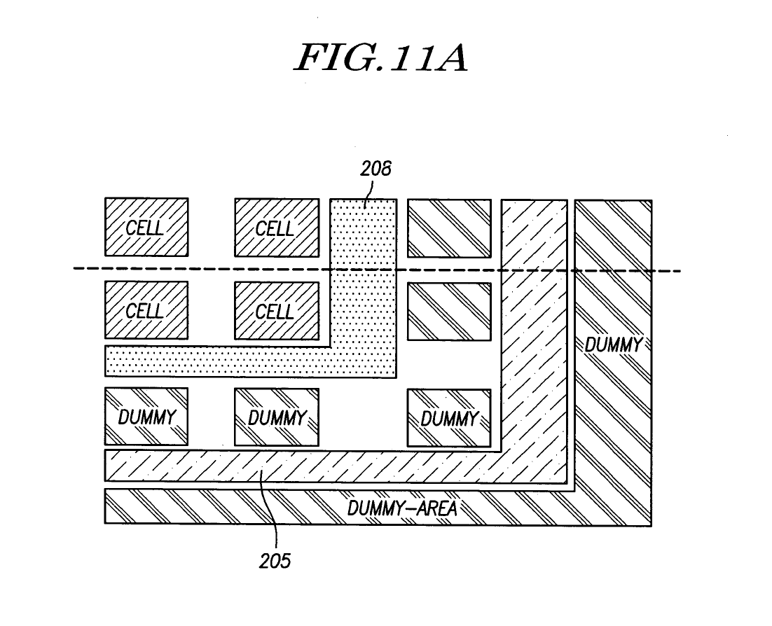

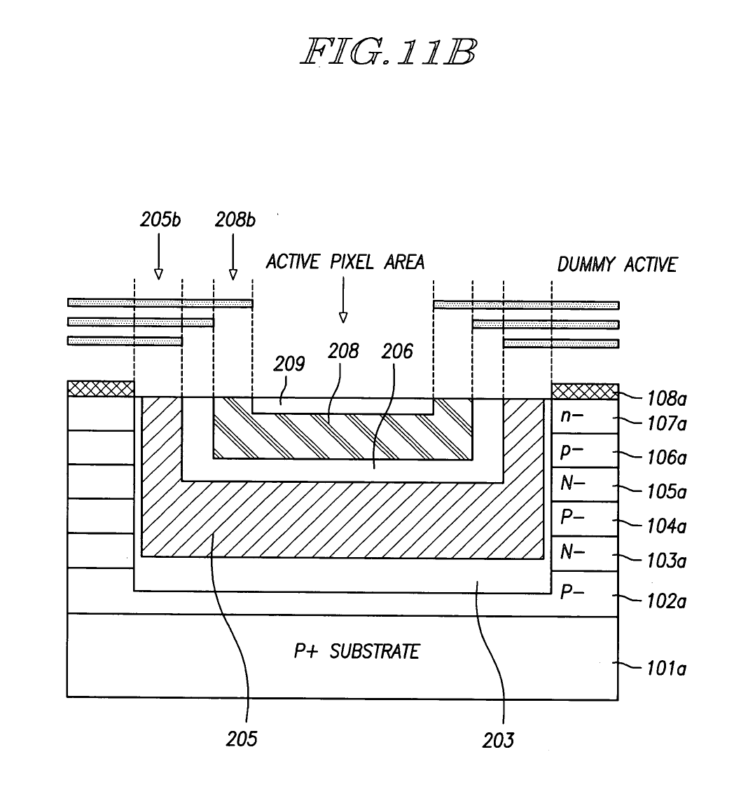

FIG. 11A is a plan view illustrating a contact structure in a vertical image sensor according to the present invention, and FIG. 11B is a sectional view showing the vertical image sensor, which is taken along a dashed line shown in FIG. 11A. Fundamentally, trench type gate contacts may be formed at outer border areas of the whole pixel area. In addition, the trench type gate contacts may surround all pixel areas at the outer border areas or exist only in a predetermined area.

FIG. 11A shows a cell area, a trench type first gate contact area 205, a trench type second gate contact area 208, and a trench area for isolation which are found from one corner of the outer border area. The trench type second gate contact area 208 is interposed between the cell area and the trench type first gate contact area 205. In addition, dummy cell areas may exist between the trench type second gate contact area and the trench type first gate contact area so as to facilitate isolation of the contact areas 205 and 208 from each other.

FIG. 11B is a sectional view taken along the dashed line shown in FIG. 11A. The a first transfer gate 205, a second transfer gate 208, and the contact plugs and contact areas 205b and 208b of the first and second transfer gates 205 and 208 can be seen in the trench. The manufacturing procedure of the above elements can be performed based on the above-mentioned method as shown in FIGS. 6A to 6J, with some minor modification. For example, the horizontal bars above the gate/gate contact structure extending to the vertical dashed lines represent masks that can be formed on the various layers of the gate/gate contact structure during its fabrication to protect contact structures 205b/208b and the insulating layers between contact structures 205b and 208b and between contact structure 205b and the vertical color detectors in a unit pixel (or cell area).

The present invention provides schemes of using three masks and two masks in order to form a trench type gate. Hereinafter, a method for manufacturing the vertical image sensor employing three masks according to the present invention will be described.

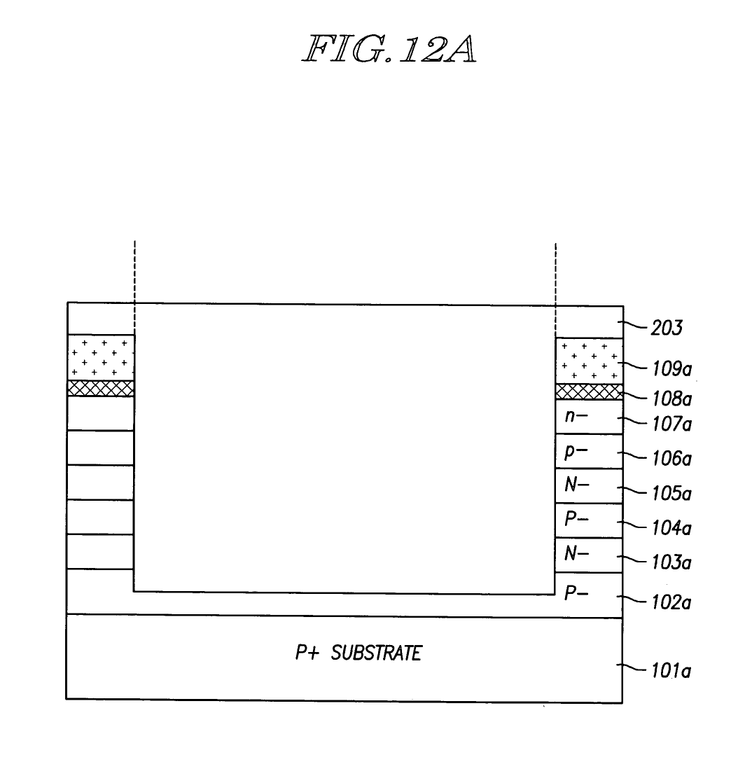

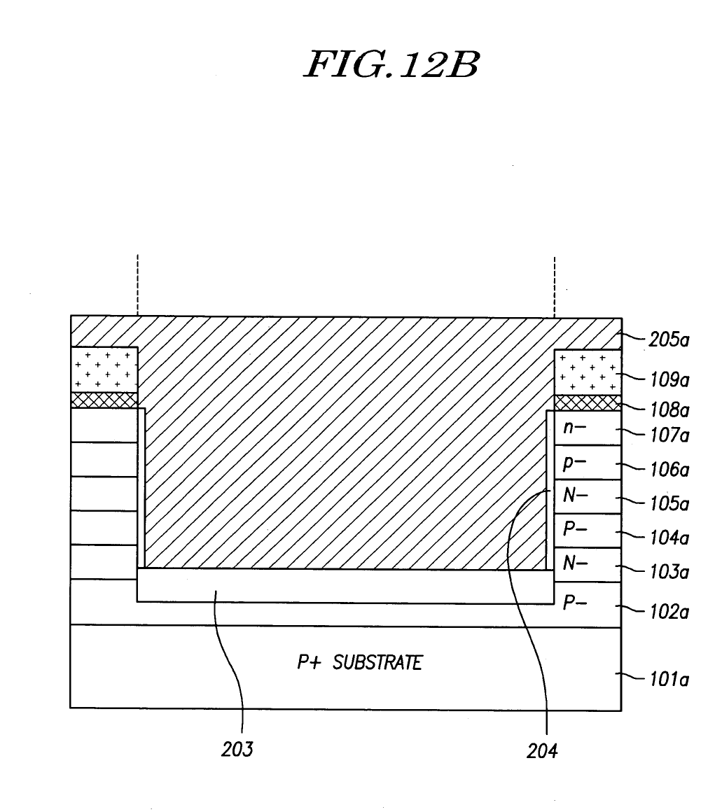

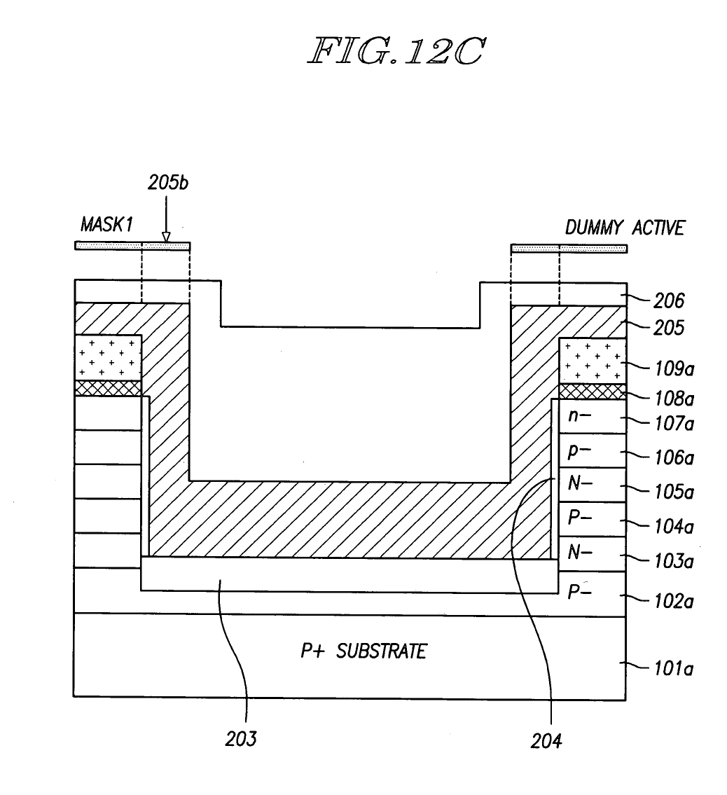

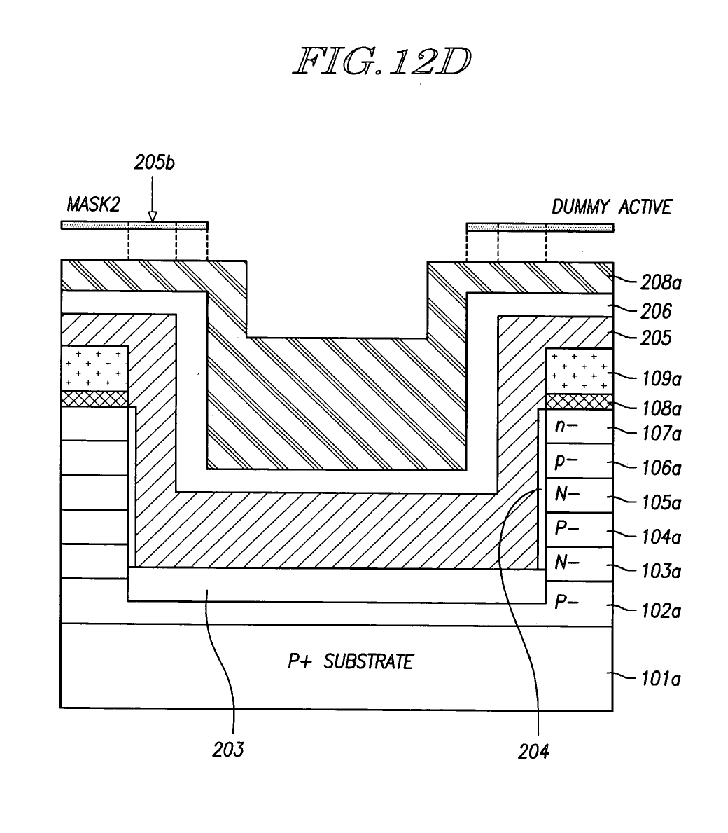

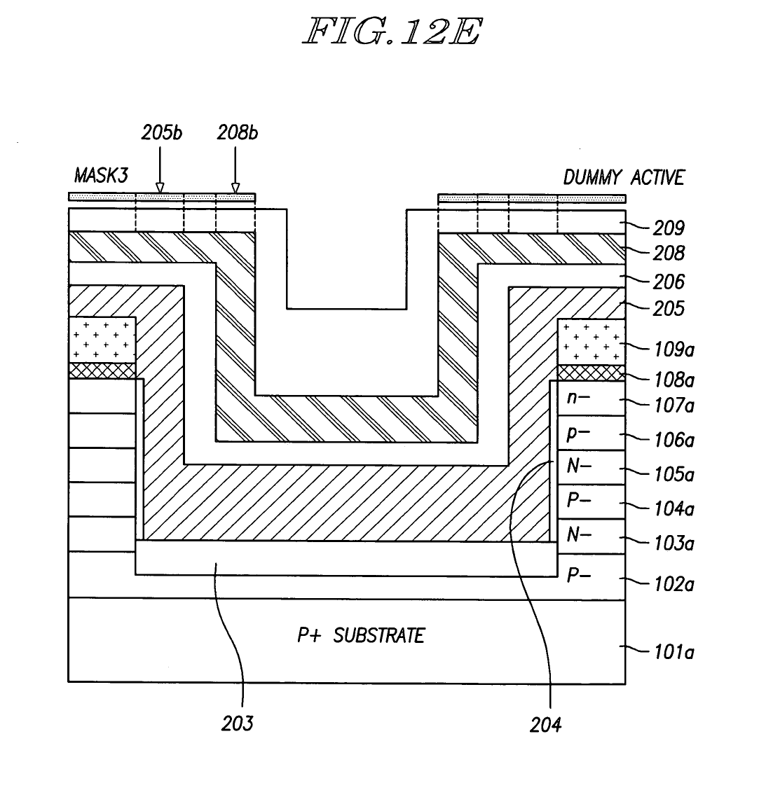

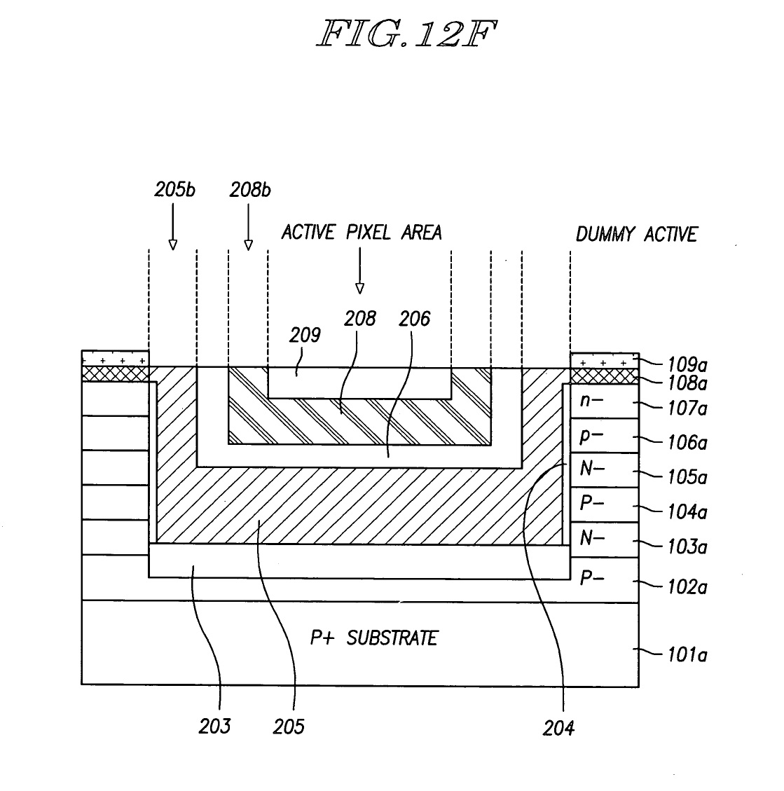

FIGS. 12A to 12F are sectional views showing a method for manufacturing the vertical image sensor according to the present invention.

As shown in FIG. 12A, the first epitaxial silicon layer 102a having the first conductive type (P type), the layer 103a having the second conductive type (N type), the layer 104a having the first conductive type, the layer 105a having the second conductive type, the layer 106a having the first conductive type, and the layer 107a having the second conductive type may be sequentially stacked on the first conductive type (P type) semiconductor substrate 101a. Then, a buffer oxide layer 108a and a nitride layer 109a are sequentially formed on the entire surface of the semiconductor substrate 101a, and the nitride layer 109a and the buffer oxide layer 108a are selectively patterned through a photolithography process, thereby defining a trench area. Then, the exposed part of the upper surface of substrate is selectively removed (e.g., by etching to a depth into the silicon epitaxial layer 102a) using the patterned nitride 109a and buffer oxide layer 108a as a mask, thereby forming a trench having a predetermined depth. Then, the first insulating layer 203 is formed on the entire surface of the semiconductor substrate 101a, including in the trench.

As shown in FIG. 12B, the first insulating layer 203 is selectively removed (e.g., by etch back) such that the first insulating layer 203 remains only in the lower part of the trench with a predetermined thickness, as discussed above. Thereafter, an oxidation or deposition process is performed with respect to the semiconductor substrate 101a, thereby forming the first gate insulating layer 204 at sidewalls of the trench (refer to FIG. 6F and the corresponding discussion thereof). Then, a silicon layer containing the second conductive type dopant is deposited onto the entire surface of the semiconductor substrate 101a, including in the trench, and annealed, thereby forming the first polysilicon layer 205a.

As shown in FIG. 12C, a first mask layer MASK1, in which a gate area and a contact plug area are defined, is formed on the first polysilicon layer 205 and aligned on the upper part of the semiconductor substrate 101a, and the first polysilicon layer 205a is selectively etched using the first mask layer MASK1 as a mask, thereby forming the first transfer gate 205 and a contact plug (refer to FIG. 6F). When the etching process is performed using the first mask layer, the contact plug of the first transfer gate 205 and the polysilicon layer 205a formed in the contact area of the contact plug may not be removed, but remain. Then, the second insulating layer 206 is formed on the entire surface of the semiconductor substrate 101a, including the first transfer gate 205, generally by deposition. The second insulating layer 206 may comprise, e.g., silicon dioxide.

As shown in FIG. 12D, a second mask layer MASK2 is formed on the second insulating layer 206 and arranged on the upper part of the semiconductor substrate 101a, and the second insulating layer 206 is selectively etched using the second mask layer as a mask. When the second insulating layer 206 is etched, the second insulating layer 206 remains at a bottom surface and/or a lateral surface of the trench with a predetermined thickness such that the contact plug of the first transfer gate 205 and a contact plug of a second transfer gate (to be subsequently formed) are isolated from each other.

Then, a second polysilicon layer 208a, which is doped with an N-type dopant, is deposited on the entire surface of the semiconductor substrate 101a, including the second insulating layer 206 which has been selectively etched. In this case, before depositing the second polysilicon layer 208a, a gate insulating layer may be formed on the entire surface of the semiconductor substrate 101a through an oxidation process or a deposition process, as described above.

As shown in FIG. 12E, a third mask layer MASK3 is formed on the second polysilicon layer 208a and arranged on the upper part of the semiconductor substrate 101a, and the second polysilicon layer 208a is selectively etched using the third mask MASK3 as an etching mask, thereby forming the second transfer gate 208. Preferably, the second polysilicon layer 208a is etched to a depth such that the second polysilicon layer 208a has an uppermost horizontal surface in the trench that is below the uppermost horizontal surface of the substrate (e.g., n− layer 107a) outside of the trench (or gate/gate contact area). In this case, the second transfer gate 208, the contact plug and the second polysilicon layer 208a formed in the contact area are not removed, but remain. Then, a third insulating layer 209 is formed on the entire surface of the semiconductor substrate 101a, including the second transfer gate 208.

As shown in FIG. 12F, the resultant structure is selectively planarized and the excess gate, gate contact, and gate (contact) insulator materials removed from outside the trench through a CMP process such that the upper surface of the nitride layer 109a is exposed. Thus, FIGS. 12a to 12f show a method for manufacturing the vertical image sensor using three mask layers.

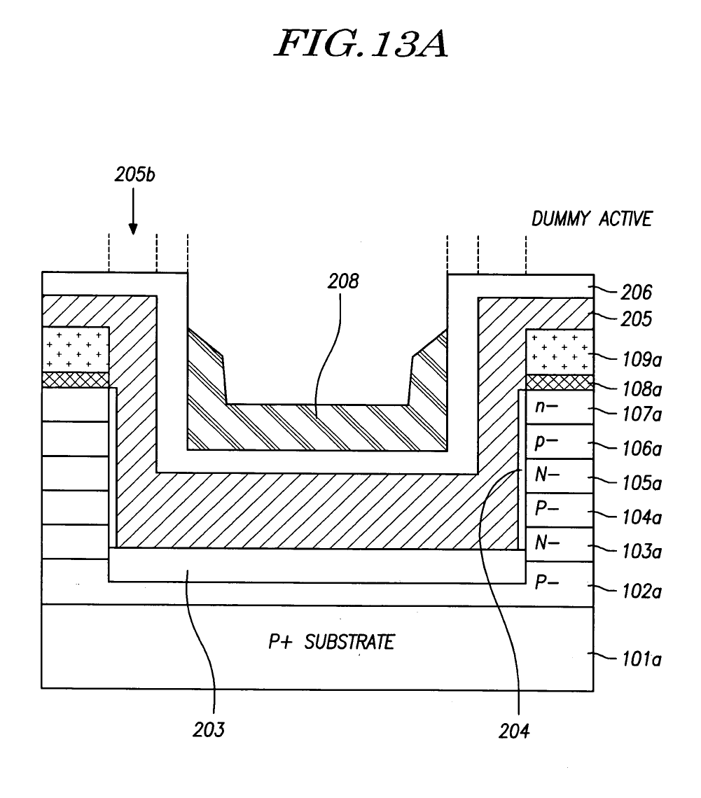

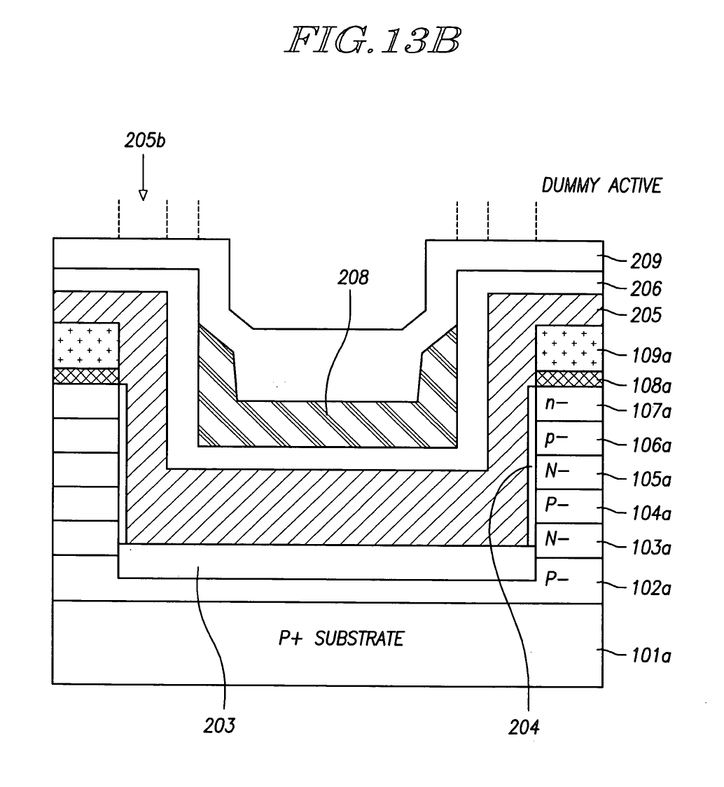

FIGS. 13A to 13B are sectional views showing a method for manufacturing the vertical image sensor using two mask layers. The method generally includes processes identical to the processes shown in FIGS. 12A to 12D.

As shown in FIG. 13A, an etching process is performed with respect to the entire surface of the poly silicon layer 208a without an additional mask (e.g., by an etch back process), thereby forming the second transfer gate 208. In this case, although the second polysilicon layer 208a is etched without a mask, sidewalls of the second polysilicon layer 208a may remain higher than the surface of the semiconductor substrate 101a(e.g., n− layer 107a) such that a contact plug and a contact area are formed. This is because a step difference derived from both the first transfer gate 205 and the second insulating layer 206 may occur between the outside and the inside of the contact area of the second transfer gate through the mask process shown in FIG. 12E.

Then, as shown in FIG. 13B, a third insulating layer 209 is formed on the entire surface of the semiconductor substrate 101a including the second transfer gate 208. The resulting structure is then planarized by CMP, as described with respect to FIG. 12F.

While the invention has been shown and described with reference to certain preferred embodiments thereof, it will be understood by those skilled in the art that various changes in form and details may be made therein without departing from the spirit and scope of the invention as defined by the appended claims.

As described above, according to the present invention, a vertical image sensor and a method for manufacturing the same have following advantages. First, RGB layers are stacked in a vertical direction, and five to six mask processes for making connection to an active pixel sensor circuit formed on a surface of a substrate can be reduced to two or three mask processes, thereby simplifying a manufacturing process of a vertical image sensor.

Second, three active pixel sensor circuits for reading out RGB signals in a conventional technology can be reduced to one active pixel sensor circuit, thereby simplifying the sensing circuitry and reducing an area in the unit pixel occupied by active pixel sensor circuitry. Accordingly, it is possible to improve an aperture ratio (the efficiency of a detection area) of the unit pixel.

Third, as the aperture ratio in a CMOS image sensor increases, the size of a pixel can be relatively reduced, so it is possible to manufacture a highly-integrated CMOS image sensor.

Fourth, only one active pixel circuit is used per unit pixel, thereby reducing the number of metal interconnections in a cell area.

What is claimed:

1. An image sensor comprising:
a semiconductor including a first conductive type substrate, a first conductive type silicon layer thereon and at least two second conductive type silicon layers thereon at different depths from a surface of the semiconductor;
a trench having a bottom lower than an uppermost surface of a first silicon layer of the second conductive type silicon layers farthest away from the surface of the semiconductor, so as to set a peripheral border area of a unit pixel;
an insulating layer in the trench in contact with an interfacial surface between the semiconductor and the trench;
a channel area in an active area between the first silicon layer and a second silicon layer of the second conductive type silicon layers without contacting the interfacial surface between the semiconductor and the trench; and
a transfer gate in the insulating layer.

2. The image sensor as claimed in claim 1, wherein the transfer gate includes doped polysilicon.

3. The image sensor as claimed in claim 1, wherein a sidewall of the trench comprises a first conductive type dopant.

4. An image sensor comprising:
a semiconductor including a first conductive type substrate, a first conductive type silicon layer thereon and at least two second conductive type silicon layers thereon at different depths from a surface of the semiconductor;
a trench having a bottom lower than a first silicon layer of the second conductive type silicon layers farthest away from the surface of the semiconductor, so as to set a peripheral border area of a unit pixel;
an insulating layer in the trench in contact with an interfacial surface between the semiconductor and the trench;
a first channel area in an active area between the first silicon layer having the second conductive type and a second silicon layer having the second conductive type higher than the first silicon layer having the second conductive type without contacting an interfacial surface between the semiconductor and the trench;
a first transfer gate in the insulating layer;
a second channel area in an active area between the second silicon layer, which has the second conductive type, and a third silicon layer having the second conductive type, higher than the second silicon layer having the second conductive type and not contacting the interfacial surface between the semiconductor and the trench; and
a second transfer gate isolated from and above the first transfer gate.

5. The image sensor as claimed in claim 4, wherein the first transfer gate and the second transfer gate include doped polysilicon.

6. The image sensor as claimed in claim 4, wherein a sidewall of the trench comprises a first conductive type dopant.

7. An image sensor comprising:
a first conductive type substrate;
a semiconductor including a first silicon layer having a first conductive type, a second silicon layer having a second conductive type, a third silicon layer having the first conductive type, a fourth silicon layer having the second conductive type, a fifth silicon layer having the first conductive type, and a second conductive type doped area in the fifth silicon layer, in sequence on the first conductive type substrate, the second silicon layer a predetermined depth from an upper interfacial surface of the semiconductor to absorb red light, the fourth silicon layer a predetermined depth from the upper interfacial surface of the semiconductor to absorb green light, and the doped area a predetermined depth from the upper interfacial surface of the semiconductor to absorb blue light;
a trench having a bottom lower than a junction boundary below the second silicon layer so as to define a border area around a pixel;
a first transfer gate in the trench and isolated from the semiconductor;
a first channel area on sidewalls of the trench between the second silicon layer and the fourth silicon layer;
a second transfer gate in the trench above the first transfer gate and isolated from the semiconductor and the first transfer gate;
a second channel area on sidewalls of the trench between the fourth silicon layer and the doped area; and
a second conductive type contact area extending to the doped area from the surface of the semiconductor.

8. The image sensor as claimed in claim 7, wherein the first transfer gate and the second transfer gate include doped polysilicon.

9. The image sensor as claimed in claim 7, wherein the sidewall of the trench comprises a first conductive type dopant.

10. The image sensor as claimed in claim 9, wherein the first conductive type dopant is a P type dopant.

11. The image sensor as claimed in claim 7, wherein the doped area is formed in the fifth silicon area through implantation.

12. An image sensor comprising:
a first conductive type substrate;
a semiconductor including a first silicon layer having a first conductive type, a second silicon layer having a second conductive type, a third silicon layer having the first conductive type, a fourth silicon layer having the second conductive type, a fifth silicon layer having the first conductive type, and a second conductive type doped area in the fifth silicon layer, in sequence on the first conductive type substrate, the second silicon layer a predetermined depth from an upper interfacial surface of the semiconductor to absorb red light, the fourth silicon layer a predetermined depth from an upper interfacial surface of the semiconductor to absorb green colored light, and the doped area a predetermined depth from an upper interfacial surface of the semiconductor to absorb blue light;
a trench having a bottom lower than a junction boundary below the second silicon layer so as to define a border area around a pixel;
a first transfer gate in the trench and isolated from the semiconductor;
a first channel area on sidewalls of the trench between the second silicon layer and the fourth silicon layer;
a second transfer gate in the trench above the first transfer gate and isolated from the semiconductor and the first transfer gate;
a second channel area on sidewalls of the trench between the fourth silicon layer and the doped area;
a second conductive type contact area extending to the doped area from the surface of the semiconductor; and
a source follower transistor having the second conductive type, in the fifth silicon layer and having (i) a gate connected to the second conductive type contact area, (ii) a drain, and (iii) a source connected to a voltage supply line.

13. The image sensor as claimed in claim 12, wherein the doped area comprises an ion implantation region in the fifth silicon layer.

14. The image sensor as claimed in claim 12, further comprising
a reset transistor between the second conductive type contact area and a reference voltage; and
an output transistor between a source and a column output line of the source follower transistor, the output transistor having a gate connected to a row select line.

15. [FIX]The image sensor as claimed in claim 14, wherein the first transfer gate and the second transfer gate include first conductive type doped polysilicon and second conductive type doped polysilicon.

16. The image sensor as claimed in claim 14, wherein the sidewall of the trench comprises a first conductive type dopant.

17. The image sensor as claimed in claim 16, wherein the first conductive type dopant comprises a P type dopant.

18. The image sensor as claimed in claim 14, wherein the doped area comprises an ion implantation region in the fifth silicon layer.

19. An image sensor, comprising:
a P+ type substrate;
a semiconductor including a first P type silicon layer, a first N type silicon layer, a second P type silicon layer, a second N type silicon layer, a third P type silicon layer, and an N type doped area in the third P type silicon layer, in sequence on the substrate, the first N type silicon layer a predetermined depth from an upper interfacial surface of the semiconductor to absorb red light, the second N type silicon layer a predetermined depth from the upper interfacial surface of the semiconductor to absorb green light, and the N type doped area a predetermined depth from the upper interfacial surface of the semiconductor to absorb blue light;
a trench having a bottom lower than a junction boundary below the first N type silicon layer so as to define a border area around a pixel;
a first transfer gate in the trench and isolated from the semiconductor;
a first channel area on sidewalls of the trench between the first N type silicon layer and the second N type silicon layer;
a second transfer gate in the trench above the first transfer gate and isolated from the semiconductor and the first transfer gate;
a second channel area on sidewalls of the trench between the second N type silicon layer and the N type doped area; and
a second conductive type contact area extending to the N type doped area from the surface of the semiconductor.

20. The image sensor as claimed in claim 19, wherein the first transfer gate and the second transfer gate include N+ doped polysilicon or P+ doped polysilicon.

21. The image sensor as claimed in claim 19, wherein the sidewall of the trench comprises a P type dopant.

22. The image sensor as claimed in claim 19, wherein the N type doped area comprises an ion implantation region in the third P type silicon layer.

23. The image sensor as claimed in claim 19, further comprising an N channel source follower transistor, in the third P type silicon layer and having a gate connected to the N type contact area and a drain and a source connected to a voltage supply line.

24. The image sensor as claimed in claim 23, further comprising:
a reset transistor between the N type contact area and a reference voltage; and
an output enable transistor between a source and a column output line of the source follower transistor, and having a gate connected to a row select line.

25. The image sensor as claimed in claim 19, further comprising a charge transfer transistor having a source connected to the N type contact area, a gate connected to a charge transfer line, and a floating drain connected to a gate of a source-follower transistor.

26. The image sensor as claimed in claim 25, further comprising an N channel source follower transistor, in the third P type silicon layer and having a gate connected to the floating drain contact of the charge transfer transistor and a drain and a source connected to a voltage supply line.

27. The image sensor as claimed in claim 23, further comprising:
a reset transistor between the floating drain contact of the charge transfer transistor and a reference voltage; and
an output transistor connected between a source and a column output line of the N channel source follower transistor, and having a gate connected to a row select line.

28. A method for manufacturing an image sensor, the method comprising the steps of:
forming a first silicon layer having a second conductive type on a surface of a first epitaxial layer on a first conductive type substrate;
forming a second epitaxial layer having the first conductive type on the first silicon layer;
forming a second silicon layer having the first conductive type and a third silicon layer having the second conductive type, which are separated from each other in a longitudinal direction, by implanting a second conductive type dopant onto a surface of the second epitaxial layer;
forming a trench having a predetermined depth in the first conductive type substrate such that predetermined areas of the first and third silicon layers are separated from other active areas;
implanting a first conductive type dopant onto a sidewall of the trench, electrically connecting the second silicon layer to the first conductive type substrate;
depositing an insulating material in the trench at a depth below than an upper surface of the first silicon layer;
forming a gate insulating layer on the sidewall of the trench; and
forming a transfer gate in the trench at a depth below the third silicon layer.

29. The method as claimed in claim 28, wherein the transfer gate comprises a doped polysilicon layer.

30. The method as claimed in claim 28, wherein implanting the first conductive type dopant comprises tilt implanting a predetermined portion of the sidewall of the trench while rotating the substrate.

31. The method as claimed in claim 28, wherein implanting the sidewall of the trench with the first conductive type dopant comprises a thermal process under a dopant gas atmosphere.

32. The method as claimed in claim 28, wherein forming the gate insulating layer comprises depositing a thin insulating film or oxidizing an exposed silicon or semiconductor surface.

33. The method as claimed in claim 28, wherein forming the first silicon layer further comprises implanting the second conductive type dopant into the first silicon layer or performing a thermal process on the first silicon layer under a dopant gas atmosphere.

34. The method as claimed in claim 28, wherein forming the third silicon layer comprises implanting the second conductive type dopant into the third silicon layer or performing a thermal process on the third silicon layer under a dopant gas atmosphere.

35. A method for manufacturing a image sensor, the method comprising the steps of:
forming a first silicon layer having a second conductive type on a first conductive type substrate;
forming a first epitaxial silicon layer having a first conductive type on the first silicon layer;
forming, in the first epitaxial silicon layer, a second silicon layer having the first conductive type in contact with an upper part of the first silicon layer, and a third silicon layer having the second conductive type in contact with an upper part of the second silicon layer;
forming a second epitaxial silicon layer having the first conductive type on the first epitaxial silicon layer;
forming a trench having a predetermined depth in the first conductive type substrate such that portions of the first and third silicon layers are separated from other active areas;
implanting a first conductive type dopant onto a sidewall of the trench such that the second silicon layer is electrically connected to the first conductive type substrate;
forming a first isolation layer by depositing an insulating material in the trench at a depth below an upper surface of the first silicon layer;
forming a gate insulating layer on the sidewall of the trench;
forming a first transfer gate in the trench below an upper surface of the third silicon layer;
forming a second isolation layer by depositing an insulating layer in the trench below an upper surface of the third silicon layer;
forming a second gate insulating layer on the sidewall of the trench;
forming a second transfer gate in the trench; and
forming a second conductive type doped area in the second silicon epitaxial layer.

36. The method as claimed in claim 35, wherein the first and second transfer gates include doped polysilicon.

37. The method as claimed in claim 35, wherein implanting the first conductive type dopant comprises tilt implanting a predetermined portion of the sidewall of the trench while rotating the substrate.

38. The method as claimed in claim 35, wherein implanting the sidewall of the trench with the first conductive type dopant comprises a thermal process under a dopant gas atmosphere.

39. The method as claimed in claim 35, wherein forming the first and second gate insulating layers comprises depositing a thin insulating film or oxidizing an exposed silicon or semiconductor surface.

40. The method as claimed in claim 35, wherein forming the first silicon layer comprises implanting a dopant into the first silicon layer or by performing a thermal process on the first silicon layer under a dopant gas atmosphere.

41. The method as claimed in claim 35, wherein forming the third silicon layer comprises implanting a dopant into the third silicon layer or by performing a thermal process on the third silicon layer under a dopant gas atmosphere.

42. A method for manufacturing a image sensor, the method comprising the steps of:
forming a second epitaxial silicon layer having a first conductive type on a first epitaxial silicon layer on a first conductive type substrate;
forming a third epitaxial silicon layer having a second conductive type on the second epitaxial silicon layer;
forming a fourth epitaxial silicon layer having a first conductive type on the third epitaxial silicon layer;
forming a fifth epitaxial silicon layer having a second conductive type on the fourth epitaxial silicon layer;
forming a trench having a predetermined depth to a surface of the first epitaxial silicon layer such that the trench separates other active areas;
implanting a first conductive type dopant onto the sidewall of the trench such that the second epitaxial silicon layer, the fourth epitaxial silicon layer, and the substrate are electrically connected to each other;
forming a first isolation layer in the trench between the first epitaxial silicon layer and the second epitaxial silicon layer;
forming a first gate insulating layer on the sidewall of the trench;
forming a first transfer gate in the trench between the second epitaxial silicon layer and the third epitaxial silicon layer;
forming a second isolation layer in the trench between the third epitaxial silicon layer and the fourth epitaxial silicon layer;
forming a second gate insulating layer on the sidewall of the trench; and
forming a second transfer gate in the trench between the fourth epitaxial silicon layer and the fifth epitaxial silicon layer.

43. The method as claimed in claim 42, wherein the first and second transfer gates include doped polysilicon.

44. The method as claimed in claim 42, wherein implanting the first conductive type dopants comprises tilt implanting a predetermined portion of the sidewall of the trench while rotating the substrate.

45. The method as claimed in claim 42, wherein implanting the sidewall of the trench with the first conductive type dopant comprises ion implantation or a thermal process under a dopant gas atmosphere.

46. The method as claimed in claim 42, wherein implanting the sidewall of the trench with the first conductive type dopant comprises a thermal process under a dopant gas atmosphere.

47. The method as claimed in claim 42, wherein forming each of the first and second gate insulating layers comprises depositing a thin insulating film or oxidizing an exposed silicon or semiconductor surface.

48. A method for manufacturing a image sensor, the method comprising the steps of:
forming a first trench having a predetermined depth in a substrate;
forming a first isolation layer in the first trench;
forming a first gate insulating layer on a sidewall of the first trench;
depositing a first polysilicon layer doped with a first N type dopant in the first trench;
forming a first transfer gate and a contact plug having a second trench therein by selectively removing a portion of the first polysilicon layer;
forming a second isolation layer in the second trench;
forming a second gate insulating layer on a sidewall of the second trench;
depositing a second polysilicon layer doped with a second N type dopant in the second trench; and
forming a second transfer gate by selectively removing a portion of the second polysilicon layer.
